(19) United States
(12) Patent Application Publication
(10) Pub. No.: US 2006/0249478 A1
(43) Pub. Date: Nov. 9, 2006

(54) Method for protecting a substrate with gold fingers in tin-welding process

(76) Inventors: Sheng-Yuan Liu, Tai-Chung (TW); Sheng-Feng Liu, Tai-Chung (TW)

Correspondence Address: SHENG-YUAN LIU, 235 Chung-Ho, Box 8-24, Taipei, TW

(21) Appl. No.: 11/120,801

(22) Filed: May 4, 2005

(51) Int. Cl. H01B 13/00; G01R 31/00

(52) U.S. Cl. 216/13; 216/59

(57) ABSTRACT

A method for protecting a substrate with gold fingers in tin-welding process comprising the steps of: taking a substrate with gold fingers thereon; forming circuit pattern and holes on the substrate; forming holes on at least one heat-tolerant film for tin-welding; coating the at least one heat-tolerant film upon the substrate as a protecting film; positioning the at least one heat-tolerant film; pressing the at least one heat-tolerant film; passing a tin furnace; removing the dregs upon the at least one heat-tolerant film; taking the at least one heat-tolerant film; checking whether the at least one heat-tolerant film is destroyed; if the at least one heat-tolerant film is not destroyed, returning to fourth step using the at least one heat-tolerant film to another substrate; and if the at least one heat-tolerant film is destroyed, returning to first step, using another heat-tolerant film to work with another substrate.

### FIELD OF THE INVENTION

The present invention relates to circuits, and in particular to a method for protecting a substrate with gold fingers in tin-welding process.

### BACKGROUND OF THE INVENTION

In the prior art printed circuit board with gold fingers, the main concern is to remove the dregs on the substrate in the welding process so as to reduce the yield ratio. When the gold fingers are adhered by the dregs, the circuit board cannot be used.

To improve this defect, chemical adhesion tape and semi-solid chemical solution are used, but it is only used one time with the operation temperature within the range of 185-200° C. In the adhesion tape method, the temperature tolerated is too low so that if it is used in a higher time, deformation of the tapes occurs so that it cannot has a preferred covering effect and is difficult to be removed. Thereby after removing the tapes, the substrate is also adhesive so as to pollute the circuit board again to affect the stability and the yield ratio of the circuit. Thereby in the manufacturing process, some manual work must be performed and it is possible that the tapes are removed and then are adhered with new tapes. It is often that this process is performed again and again. Furthermore, the accuracy is low.

In another improved design, a semi-solid chemical material is adhered on the circuit board, which is heated and solidified and then is etched away by chemical agents. The process is very complicated and thus the cost is high.

### SUMMARY OF THE INVENTION

Accordingly, the primary object of the present invention is to provide a method for protecting a substrate with gold fingers in tin-welding process. The method comprises the steps of: taking a substrate with gold fingers thereon (step 1); forming circuit pattern and holes on the substrate (step 2); forming holes on at least one heat-tolerant film for tin-welding (step 3); placing the at least one heat-tolerant film to a fixture of a working platform (step 4); placing the substrate on the working platform (step 5); coating the at least one heat-tolerant film upon the substrate as a protecting film (step 6); positioning the at least one heat-tolerant film (step 7); pressing the at least one heat-tolerant film (step 8); passing a tin furnace (step 9); removing the dregs upon the at least one heat-tolerant film (step 10); taking the at least one heat-tolerant film (step 11); checking whether the at least one heat-tolerant film is destroyed (step 12); if the at least one heat-tolerant film is not destroyed, returning to step 4 using the at least one heat-tolerant film to another substrate; if the at least one heat-tolerant film is destroyed, returning to step 1, using another heat-tolerant film to work with another substrate.

The various objects and advantages of the present invention will be more readily understood from the following detailed description when read in conjunction with the appended drawing.

### BRIEF DESCRIPTION OF THE DRAWINGS

FIG. 1 shows the flow diagram of the present invention.

FIG. 2 shows another flow diagram of the present invention.

FIG. 3 is a first embodiment of the present invention.

FIG. 4 shows a second embodiment of the present invention.

FIG. 5 is a third embodiment of the present invention.

FIG. 6 is a fourth embodiment of the present invention.

### DETAILED DESCRIPTION OF THE INVENTION

In order that those skilled in the art can further understand the present invention, a description will be described in the following in details. However, these descriptions and the appended drawings are only used to cause those skilled in the art to understand the objects, features, and characteristics of the present invention, but not to be used to confine the scope and spirit of the present invention defined in the appended claims.

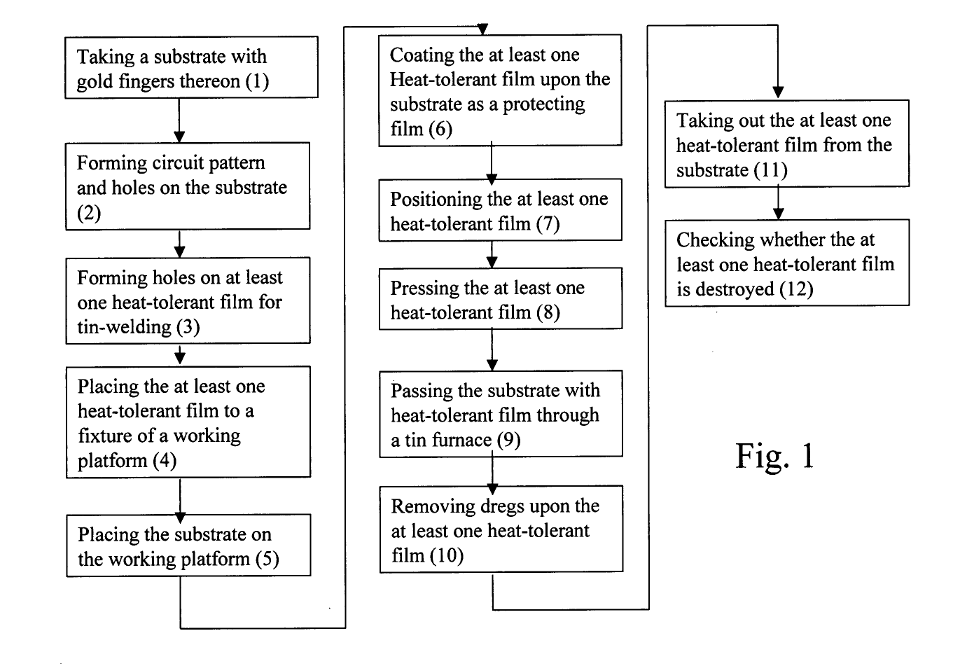

Referring to FIG. 1, a method for protecting a golden fingers on a substrate, wherein the golden fingers are a plurality of parallel pins arranged on the substrate. The method comprises the following steps.

In the present invention, the heat-tolerant film 6 is a high tensional plastic, rubber or silicon film, which can endure high temperature of 300° C. The heat-tolerant film is coated on the places to be protected before high temperature tin-welding. The heat-tolerant film 6 has a material of high extension, high adhesion, high tension, high cohesion which is suitable to be adhered on a circuit substrate so that the film can be effectively and firmly adhered upon the substrate.

The method of the present invention comprises the following steps of taking a substrate with gold fingers thereon (step 1); forming circuit pattern and holes (2) on the substrate 1; forming holes on a heat-tolerant film for tin-welding (step 3); placing the heat-tolerant film to a fixture of a working platform (step 4); placing the substrate on the working platform (step 5); coating the heat-tolerant film upon the substrate as a protecting film (step 6); positioning the heat-tolerant film (step 7); pressing the heat-tolerant film (step 8); passing a tin furnace (step 9); removing the dregs upon the heat-tolerant film (step 10); taking the heat-tolerant film (step 11); checking whether the heat-tolerant film is destroyed (step 12); if not, returning to step 4 for another substrate;, if yes, returning to first step, using another heat-tolerant film to work with another substrate.

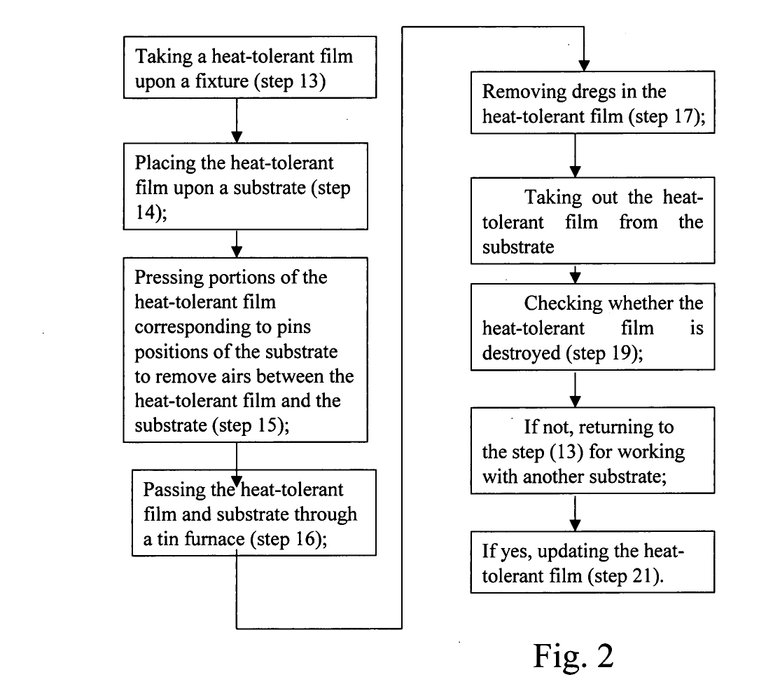

Another embodiment of the present invention is illustrated in FIG. 2. The method comprises the steps of taking a heat-tolerant film upon a fixture (step 13); then placing the heat-tolerant film upon a substrate (step 14); pressing portions of the heat-tolerant film corresponding to pins positions of the substrate to remove airs between the heat-tolerant film and the substrate (step 15); passing the heat-tolerant film and substrate through a tin furnace (step 16); removing dregs in the heat-tolerant film (step 17); taking out the heat-tolerant film from the substrate (step 18); checking whether the heat-tolerant film is destroyed (step 19); if not, returning to the step (13) for working with another substrate; if yes, updating the heat-tolerant film (step 21).

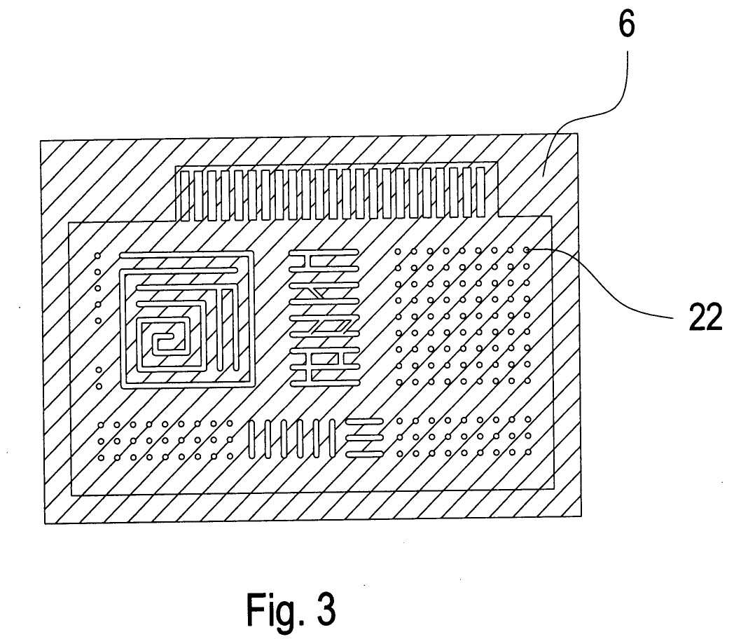

Referring to FIG. 3, an embodiment of the present invention is illustrated. A heat-tolerant film 6 is coated upon a substrate 1 with gold fingers thereon. The heat-tolerant film 6 is adhered upon the substrate 1 and the gold finger as a protecting film so as to reduce the destroy of the gold finger and substrate in welding process.

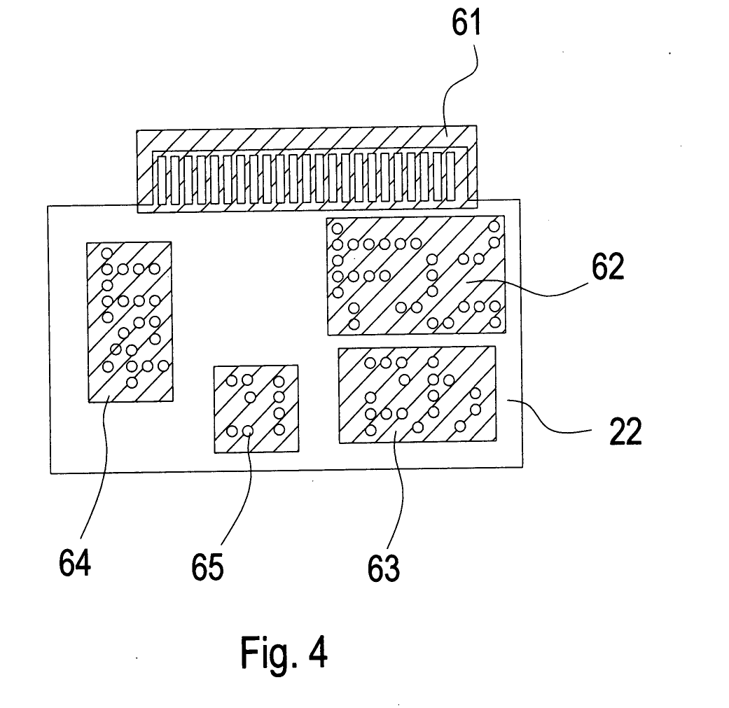

In FIG. 4, it is illustrated that the heat-tolerant films 61, 62, 63, 63 and 65 are placed upon the different portions 22 of the substrate having gold fingers for protecting the portions 22.

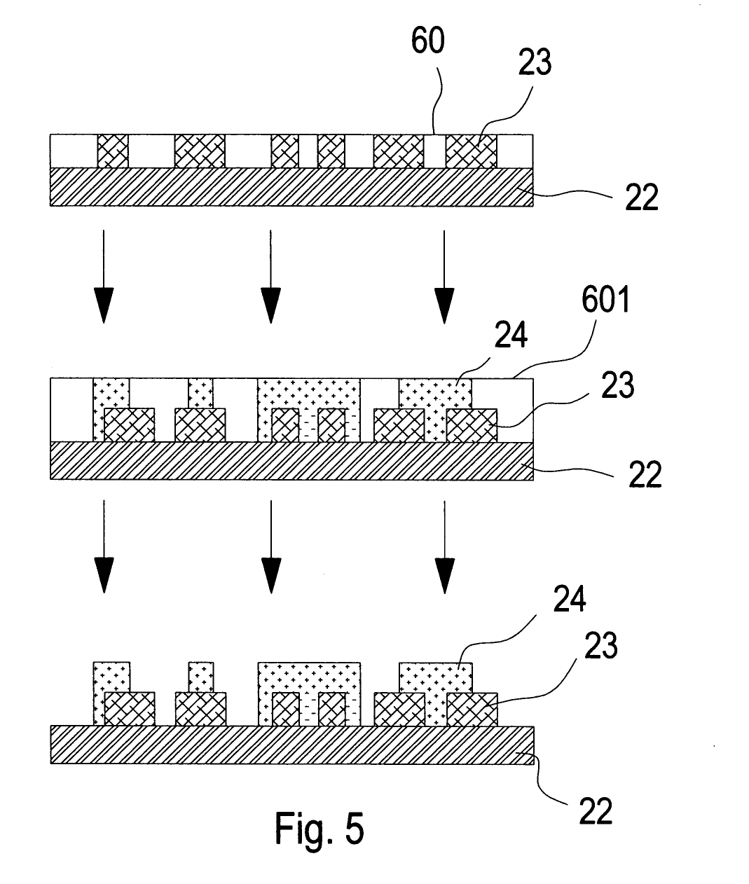

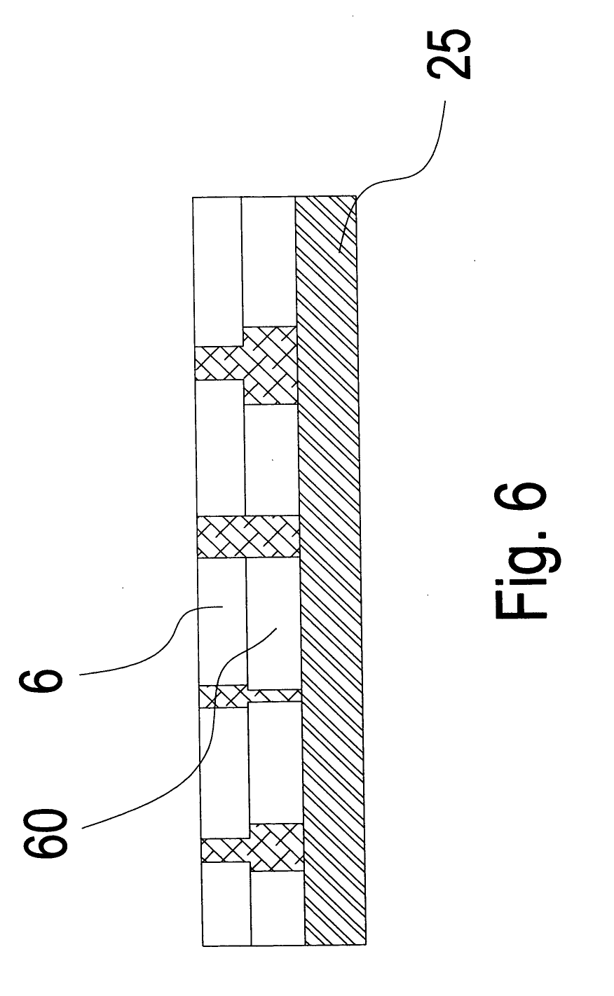

In FIG. 5, it is illustrated that the heat-tolerant film 6 is placed between a plurality of electronic elements 23 on a substrate as a first protecting heat-tolerant film; then some parts of the heat-tolerant film 6 are removed for form another plurality of electronic elements 24 and then a plurality of heat-tolerant film 601 is coated upon the first heat-tolerant film 60; then after passing a tin-furnace and removing dregs, the first and second heat-tolerant films can be removed. FIG. 6 shows another embodiment of the present invention, where a similar example as the FIG. 5 is illustrated.

Advantages of the present invention will be described in the following. The heat-tolerant film is a film of high adhesion, high tension and high cohesion, it can be used repeatedly over 200 times. No chemical adhesion is used. The operation is simple and mechanical fixing way is used.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for protecting a substrate with gold fingers in tin-welding process, the method comprising the steps of:
taking a substrate with gold fingers thereon (step 1);
forming circuit pattern and holes on the substrate (step 2);
forming holes on at least one heat-tolerant film for tin-welding (step 3);
placing the at least one heat-tolerant film to a fixture of a working platform (step 4);
placing the substrate on the working platform (step 5);
coating the at least one heat-tolerant film upon the substrate as a protecting film (step 6);
positioning the at least one heat-tolerant film (step 7);
pressing the at least one heat-tolerant film (step 8);
passing the substrate with heat-tolerant film through a tin furnace (step 9);
removing dregs upon the at least one heat-tolerant film (step 10);
taking out the at least one heat-tolerant film from the substrate (step 11);
checking whether the at least one heat-tolerant film is destroyed (step 12);
if the at least one heat-tolerant film is not destroyed, returning to step 4 using the at least one heat-tolerant film to another substrate;,
if the at least one heat-tolerant film is destroyed, returning to step 1, using another heat-tolerant film to work with another substrate.

2. The method for protecting a substrate with gold fingers in tin-welding process as claimed in claim 1, wherein the heat-tolerant film is placed upon pin portion on the substrate and the heat-tolerant film is pressed to remove air between the heat-tolerant film and the substrate.

3. The method for protecting a substrate with gold fingers in tin-welding process as claimed in claim 1, wherein the heat-tolerant film is one of a high tensional plastic, rubber or silicon film,

4. The method for protecting a substrate with gold fingers in tin-welding process as claimed in claim 3, wherein the heat-tolerant film is made of material of high extension, high adhesion, high tension, high cohesion which is suitable to be adhered on a circuit substrate so that the film can be effectively and firmly adhered upon the substrate;

5. The method for protecting a substrate with gold fingers in tin-welding process as claimed in claim 1, wherein the heat-tolerant film endures high temperatures over 300° C.

6. The method for protecting a substrate with gold fingers in tin-welding process as claimed in claim 1, wherein the heat-tolerant film is cut to have various shapes to be adhered on the substrate.

7. The method for protecting a substrate with gold fingers in tin-welding process as claimed in claim 1, wherein the heat-tolerant film is formed with hollow spaces to be placed upon a substrate with electronic elements protruded on the substrate.

8. The method for protecting a substrate with gold fingers in tin-welding process as claimed in claim 1, wherein the heat-tolerant film is placed on the substrate manually or mechanically.

9. The method for protecting a substrate with gold fingers in tin-welding process as claimed in claim 1, wherein at least one medium is added to the heat-tolerant film to be formed with different holes matching a circuit on the substrate.

10. The method for protecting a substrate with gold fingers in tin-welding process as claimed in claim 1, wherein the heat-tolerant film is used as a heat isolation film to protect the substrate, gold finger and electronic elements.

11. The method for protecting a substrate with gold fingers in tin-welding process as claimed in claim 1, wherein there are a plurality of heat-tolerant films being adhered on the substrate to protect different areas of the substrate.

12. The method for protecting a substrate with gold fingers in tin-welding process as claimed in claim 1, wherein a plurality of layers of heat-tolerant films are adhered upon the substrate one by one by protecting electronic elements of different elevations.
